(19) United States
(12) Patent Application Publication
(10) Pub. No.: US 2005/0264303 A1
(43) Pub. Date: Dec. 1, 2005

(54) Radiation monitoring of body part sizing and use of such sizing for person monitoring

(76) Inventors: Kenneth S. Bailey, Longboat Key, FL (US); Fernando A. Barrera, West Hills, CA (US)

Correspondence Address: FISH & RICHARDSON, PC, 12390 EL CAMINO REAL, SAN DIEGO, CA, 92130-2081, US

(21) Appl. No.: 11/056,945

(22) Filed: Feb. 11, 2005

Related U.S. Application Data
(60) Provisional application No. 60/544,691, filed on Feb. 12, 2004.

(51) Int. Cl. G06K 9/00; G01R 27/04

(52) U.S. Cl. 324/644; 382/115; 713/186; 340/5.83; 340/552; 340/573.1; 382/132

(57) ABSTRACT

A person monitoring system that may determine personal characteristics and compare them to other characteristics without necessarily recognizing a specific individual corresponding to those characteristics. An embodiment may use a first array of focused microwave transmitting antennas driven by a microwave transmitting electronics, producing microwave signals for the first array. A second array of focused microwave receiving antennas may have each antenna of said second array being focused and pointed to receive a microwave transmission from a specific antenna of the first array. A controller determines pixels of the sillouette of the monitored subject, as pixels from the microwave antennas. Parameters of human body shape are determined, and used as a profile that can be monitored.

This application claims priority to U.S. provisional application Ser. No. 60/544,691, filed Feb. 12, 2004, the disclosure of which is incorporated by reference.

### BACKGROUND

Techniques to determine and verify the identity of a person are well-known. Law enforcement and criminal investigations often require positive identification of an individual. This can be done from positive identification mechanisms such as a photograph, fingerprinting, voice scanning, handwriting, DNA testing, or other similar technique. Positive identification techniques cannot identify an individual without an initial profiling step. Typically, an individual is photographed, fingerprinted or blood tested for that profiling.

Surveillance cameras are also commonly used to maintain photographic monitoring of various locations.

Since the terrorist attacks of 9/11, heightened security measures have come into effect. The Homeland security act of 2001, for example, enabled law enforcement agents to arrest, detain, search and fingerprint individuals at random. It is also commonplace for public buildings to require certain security procedures prior to entry. Higher security areas, such as airports, federal buildings, public arenas and exhibition areas, have a higher level of scrutiny.

The technique of choice for identification of individuals remains fingerprinting, probably because of the depth of the fingerprint databases which correlate the individual fingerprints to individual identities. More recently, a DNA database has also been used to identify individual DNA profiles. These techniques may be used at a crime scene, to analyze individual aspects left behind.

Different kinds of body scanners are known. External type body scanners such as metal detectors can detect a user holding some kind of metal item. Internal devices such as MRI, CAT scan or ultrasound have also been used to view inside a person's body, usually for the purpose of detecting medical conditions.

### SUMMARY

The present disclosure describes techniques which can be used to recognize individual body characteristics with or without a template to which to compare those body characteristics. Profiling of individuals is discussed. One aspect allows monitoring individual movements, without specific identification of specified individuals, but correlates characteristics of individuals to other similarly determined characteristics.

Profiling of those body characteristics is also described. One aspect of this system allows effective use in real-time to monitor individual identities. No sample or body part is required.

### BRIEF DESCRIPTION OF THE DRAWINGS

These and other aspects will now be described in detail with reference to the accompanying drawings, wherein:

FIG. 1 shows a system diagram;

FIG. 2 shows an electronics block diagram;

FIG. 3 shows a flow chart of operation;

FIG. 4 shows a stick form of a subject with parameters and

FIG. 5 shows a system diagram with connectors.

### DETAILED DESCRIPTION

Many of the previous used identification techniques have relied on known individual characteristics of users. The present technique makes use of distinguishing differences between individuals. There are many recognizable features of individuals. These features allow one person to recognize another, from front, back, or side. For example, even the silhouette of a known person under cover of darkness is often sufficiently distinguishable to allow determination of the person's identity. These personal characteristics are obtained and used for monitoring. The personal characteristics themselves are monitored, and the specific identity corresponding to those characteristics need not be determined prior to the monitoring.

The present system can enable automatically monitoring those characteristics, to determine where the person with those characteristics, known or unknown, has been in recent past. For example, a person can be determined to have been in the airport facility in 10 different cities and 11 banks in the last three weeks. This enables maintaining a profile of the person's movements. The identity corresponding to that person can be known or unknown. Moreover, all of this can be easily done without the person's knowledge and consent, since no previous model of person or looks is necessary. According to the present system, it is only necessary for the current data to be compared to other similarly obtained data.

One application of the present techniques is for use in egress or ingress to some area. For example, this can be used to control access to a government installation or facility, to an airport, or to any high security facility. The detection system is hidden in various locations. Employees go about their regular duties. Their passage in certain locations is detected. The data is compared against employee profiles, and any un-recognized profile is signaled as an unauthorized presence.

In one aspect, the user is profiled, and identified as being an authorized user. As the user passes through various areas such as halls and doorways, they can be monitored by this system. Surreptitious monitoring is possible as described herein. Importantly, uniforms, disguises, and the like will not confuse the monitoring. Facial hair, and other hair color etc. also will not confuse this system.

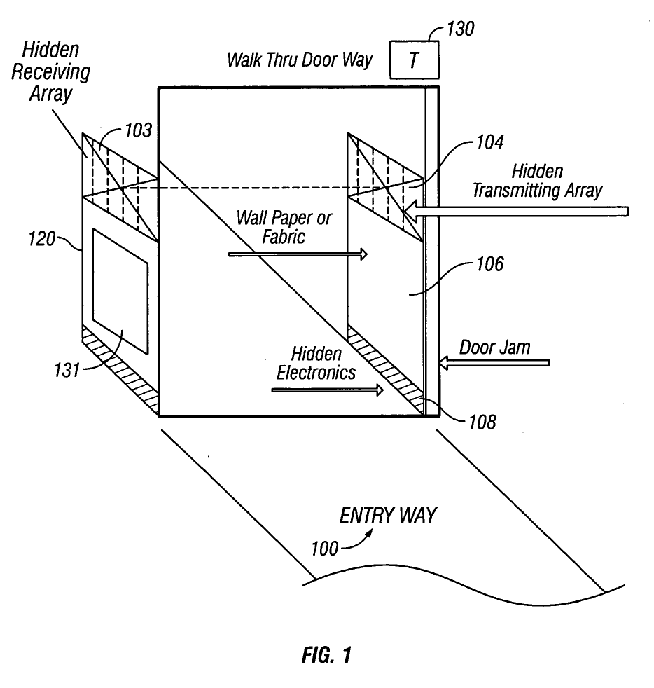

FIG. 1 shows an embodiment which uses a combination of radiation transmissions, herein microwaves, of various types to obtain a profile of a subject. The individual's profile is captured and stored. The capturing of the image can occur while the user is running or walking.

Another aspect of the system enables profiling ethnic groups by race and gender for access screening purposes. The system may be used for law enforcement, crowd control, monitoring, typing and tracking of the suspects.

This system may use low-level microwave energy as is described in U.S. patent application Ser. No. 09/751208 which is herein incorporated by reference. The system can illuminate the subject from one side 104 with radiation, as well as from above or from some other angle. Using the analogy of an electric incandescent bulb which casts a shadow on the wail, a receiving array 105 receives the virtual silhouette of the subject. Both transmitting and receiving arrays may include a plurality of miniature focused antennas, such as parabolic antennas 104, 105. The data profile is received as the user passes between the sending and receiving antennas. In one aspect, an array of microsized antennas are used, each transmitting antenna is focused towards a specified receiving antenna. Each transmitting and receiving antenna pair effectively forms a “pixel” of a final received “image”. That “image” is then characterized. Alternatively, other kinds of radiation can be used to characterize the individual.

One important aspect of the system is that it is susceptible of being hidden in various different ways. The system may be used for screening access doors and corridors without being noticed by the people being screened.

FIG. 1 shows an embodiment of a scanner formed of an array of transmitting and receiving antennas. Both can be hidden, e.g. in a wall, or within a dedicated structure. One such structure may be a pillar which looks like a conventional department store security tag monitoring system. FIG. 1 shows the entryway 100 leading through a door jamb. This entry area is one through which people pass during a normal course. Entry or exit from specified locations can also be monitored by the system.

According to the embodiment, a transmitting array 104 is formed of antennas hidden behind a wallpaper or fabric covering 106. The transmitting array 104 is powered by electronics 108 would drive the transmitter. Analogously, a receiver array 120 is located on the opposite side of the door jam. Each element of the receiver array receives microwave information from a corresponding transmitter, unless interrupted by the passage of a subject. A controller element is responsive to the data received by the receiving array, and forms a profile based on the data it receives from the receiving array. That profile is indicative of specific characteristics of an individual.

Resolution may be increased by using a higher frequency microwave signal. In one aspect, therefore, a signal above 150 GHz may be preferred. Since the wavelength of the 150 GHz signal is approximately 2 mm, this may provide a resolution of about 1 mm overall of the individual's characteristics. Each antenna may be a parabolic antenna with ½-25 mm diameter. The size of the individual antennas sets the pixel size of the points, so a smaller antenna may provide more resolution. The antennas may also be printed on a circuit board, or formed in silicon or using micromachining techniques.

The microwave energy can be used over a number of different distances. In one embodiment, there may be less than 4 feet between the transmitting array and the receiving array. In this embodiment, the output power may be extremely low, e.g. below the accepted environmental norm level of 10 mW per centimeter square. This low power and invisibility of the system makes this system very useful for various purposes.

Another set of transmitting/receiving antennas 130, 131 may illuminate the subject and detect information from a different angle.

According to different aspects of this system, the microwave may be used to illuminate the subject's head, torso, spinal curvature, bone structure, nose, neckline curvature and/or profile or other direction. The information may be used to identify an individuals data and the data used for monitoring of various types. The monitoring may include following whereabouts without being required to identify an individual, or for profiling such as race or gender profiling in locations. For example, different ethnic groups have different physical characteristics, and males have different characteristics than females. This system may be used to profile the kinds of people that enter a location.

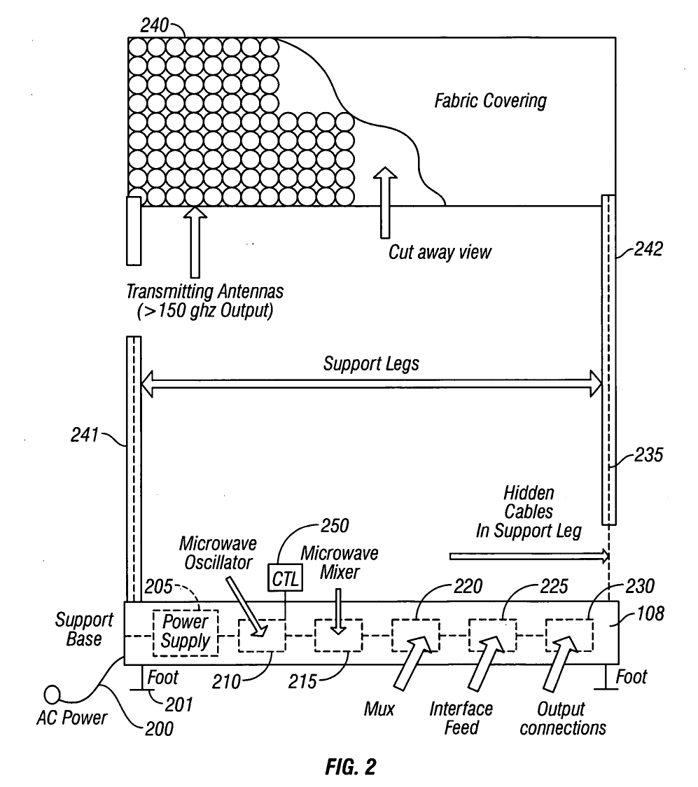

FIG. 2 shows a block diagram of the electronics 108. This may be on the bottom portion of the unit. The array 240 may be located on a base, shown as a foot portion 241, 242. This may raised off the ground for cooling purposes or other purposes.

AC power 200 is input to a power supply 205, that receives the AC power 200, and forms different kinds of power which are used by the subassemblies. A microwave oscillator 210 is powered by the power supply 205. The microwave oscillator 210 also drives a microwave mixer 215. The output of the microwave mixer 215 is multiplexed by a multiplexer 220, to an interface 225. Interface 225 drives the output connections 230, which leads to a cable array 235. The cable array 235 carries a plurality of different outputs, the different outputs respectively being coupled to the respective antennas in the transmitting array. The transmitting array 240 includes a plurality of different miniature parabolic antennas completely filling a space defining the space to be monitored. Each of the different antennas may be located such that the edges of one antenna are pressed against edges of all the neighboring antennas, thereby completely filling the space within which the array can be located. In the embodiment, the array may be for example 9-50 antennas tall, and may be between 15 and 250 antennas wide. Each transmitting antenna transmits focused microwave.

The transmitting antennas preferably encompass an area which transmits microwave over the location from a user's torso to the top of the user's head. For example, this may cover the area between 2½ feet from the floor, and 6½ feet from the floor, to acquire data from all desired parts of 95% of the population.

An array of receiving antennas is located facing the transmitting antennas, so that each receiving antenna is pointed at a specific transmitting antenna. The receiving antenna array is similarly sized to the transmitting array, and also covered by a fabric covering.

Support legs 241, 242 may hold up the antenna arrays; or alternatively the antenna array may be mounted on a wall, which holds up the antenna array. As previously discussed, a fabric covering may cover the antenna.

The entire operation is controlled by the controller 250, which may be a microcontroller or suitably programmed processor. The controller 250 may operate to control the transmission and reception, and to form data indicative thereof.

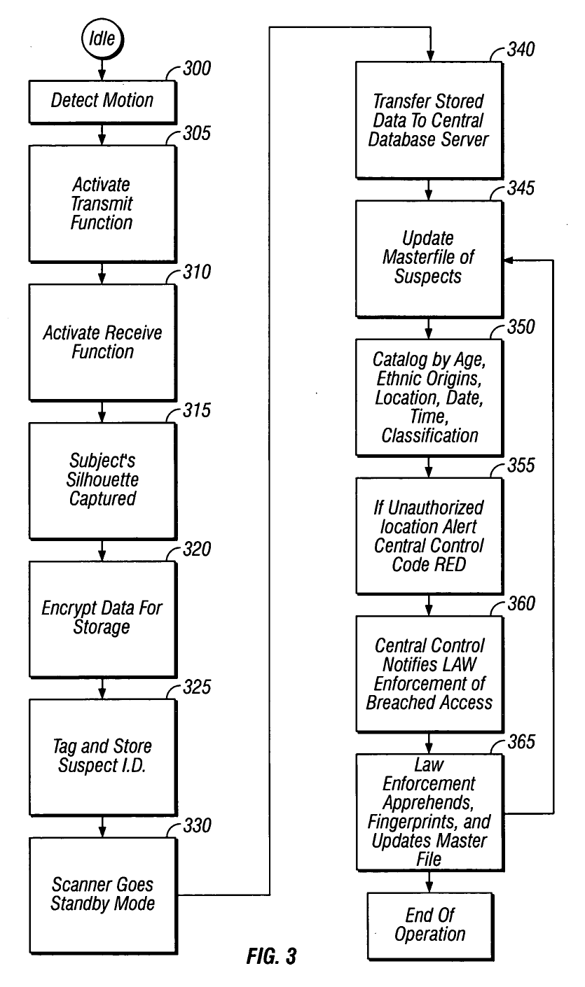

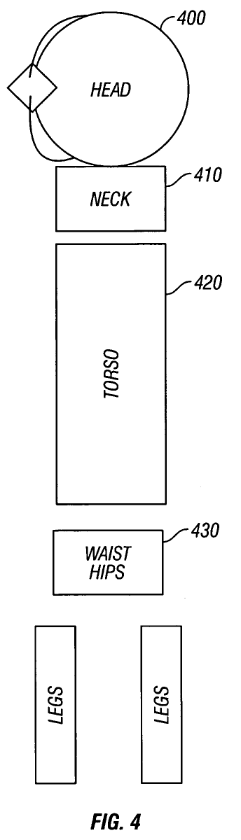

The system may operate as shown in FIG. 3. At 300, the system detects motion. Motion may be detected, for example, by detecting an interruption in microwaves between the transmitter and receiver at any one location. Motion may also be detected by a dedicated motion sensor device, such as an ultrasonic device in order to save power, for example. After the motion is detected at 300, the transmit function is activated at 305. This causes the antennas to transmit. The receive function is activated at 310, which may be at the same time as or substantially similar time to the transmit function at 305. At 315 the subject's silouette is captured, and changed into raw data. This may be done as follows. Each receiving antenna is coded with its location, for example, 4.32 feet high, 6.2 feet into the array. As the subject walks, the data from all the transmitting antennas is progressively interrupted to the receiving antennas. This forms a silloutted profile of the person. The shape of the sillouette is converted to parameters representative of various body parts, in accordance with the parameter conversion of FIG. 4. The data, representing a set of information, is then stored at 320. The information may be encrypted, especially if it will be sent over open network lines.

The information may be compared to other sets of information to either recognize or correlate the sets against other sets, or may simply be stored with the subject at 325. This completes the operation of the scanner, and consequently the scanner goes into the standby mode at 330. The data may then be transferred to the central database server at 340.

The central database server maintains a master file of subjects, allowing maintaining surveillance of their movements. At 345 the data is categorized to include location, date, time and any other classification. When used for access control, this will detect an unauthorized person being in an unauthorized location. This issues a code red alert causing central control to notify law enforcement of the breach to access at 360 allowing law enforcement to apprehend 365.

FIG. 4 shows the parameters of a subject which may be obtained. Any and all of these parameters may be obtained. 400 shows the head of the subject, with the statistics which are obtained including head overall shape, forehead curvature, nose size and slant; chin slant and angles; head diameter overall; head ratio height versus width. Note that each of these head statistics may be assigned with a numerical designation representing the parameter, and also a point of data from the analysis.

Analogously, the neck statistics may be obtained including length; diameter; neck to head ratio; curve of Adams Apple.

The torso 420 is also categorized according to overall length; width at centerline; curvature of stomach; fat ratios; torso type; where the torso type can be one of a number of different types shown here as stick, spoon, wedge, pear, but of course the torso may be other kinds of shapes also. Finally, spinal curvature is assessed as part of the torso parameters.

The waist 430 is analyzed to obtain diameter; hip length; curvature of hip; curvature of pelvis; angle of hip.

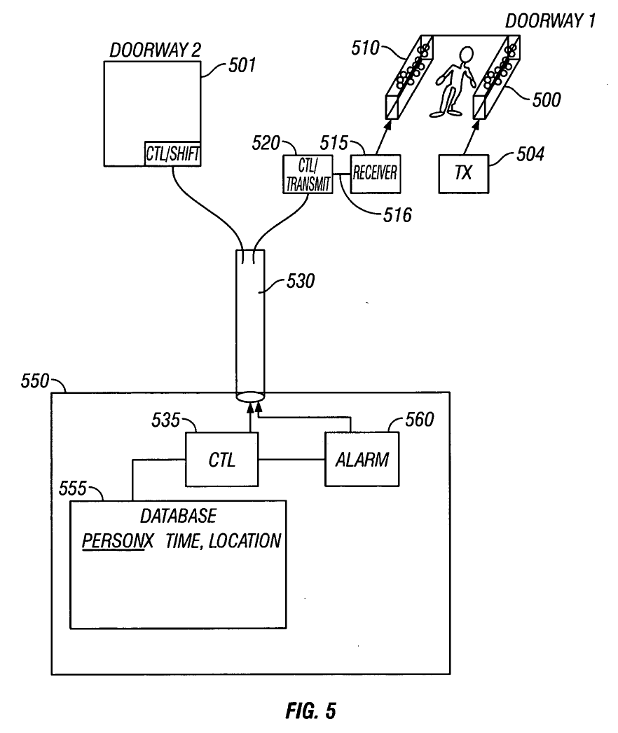

FIG. 5 shows an overall block diagram of the overall system and how it may be used. One aspect of the system is to hide the characteristic analyzing portion within a doorway. FIG. 5 shows doorway 501 with an analyzing portion therein. In one aspect, the doorway may be sufficiently narrow so that only a single person can traverse it at any given time. In addition, the characterizing antennas maybe located along multiple planes. For example, while FIG. 1 shows the characterizing antennas substantially lateral to the person, there may also be transmitting and receiving antennas from other directions in order to obtain additional three-dimensional views of the parameters. Different views obtained at different times may be correlated with one another to obtain a three dimensional aspect of the information about the person.

Doorway 501 includes an array of transmitting antennas 502 driven by the transmitting electronics 504 and an array of receiving antennas 510. The information received by the receiving antennas is processed by a receiver 515 which includes a processor therein. In one aspect, each transmitting antenna may be pointed directed at another antenna in the receiving array.

This can allow analyzing and determining the shape of the person based specifically on which antennas received and transmitted at any given time. The antennas may all transmit at the same time, or may transmit in time bursts, with reception also timed to the same time bursts. The processor analyzes which transmissions it has received at which time, and produces an output 516 based thereon. The output may simply be raw data, and is sent by controller transmitter 520 over a common network 530. The network may be a secure network, may be the Internet, or may be a telephone line. In the case of using a public network, the data may be encrypted prior to sending.

Similarly, this system may be located in a number of different doorways. FIG. 5 shows generically doorway 501 which is a different doorway in a different location, also receiving information about the user. However, this system may be located in a number of different doorways in a number of different areas.

The data over network 530 is processed by the controller 535 in the central database server 550. The controller analyzes the data to attempt to determine a match between this data and previously obtained data. A master database file 555 is maintained, which may include information for each of the plurality of different persons. That information may include the time and location when the person has been at different areas.

Importantly, a person need not be individually identified. When specified statistics are obtained, that set of statistics becomes a new profile, profile x. The central database servers need not know specifically individual identifying information about profile x, but can still maintain surveillance of profile x. if characteristics in either the database or the access trigger an alarm at 560, the alarm is sent back over the network 532 to the location. The authorities can then find the person corresponding to profile x, apprehend person acts, allowing the central database to be updated with more information about the identity of the person corresponding to profile x. However, the lack of identity does not stop the database from maintaining information about the person.

This may also allay privacy concerns, since the database knows the person only by their physical characteristics and not necessarily by their specific identity. In addition, since the specific identity does not need to be found, this system facilitates tracking people without any initial registration of the person's identity at all.

The above has described one way of determining a person's physical characteristics. However, it should be understood that the basic concepts which are described herein can be extended to other methods of detecting a person's basic characteristics. In fact, this represents a totally new paradigm; whereby a person's physical characteristics are used to track the person without initial registration of those physical characteristics, and hence without specifically knowing who that person represents.

According to another embodiment, the system may be used for profiling animals. Show horses are still measured with paper measuring tapes for features that make it a prize bloodline for rating and judging purposes. The present measuring system could be used for horses, show dogs, bulls, pigs, cows, chickens etc to see if they are up to par, wrestlers, prize fighters, football players, hockey players etc.

Moreover, even though the above has described certain physical characteristics, it should be understood that this system is also intended to cover all other physical characteristics such as foot size and length, hand size and length and the like.

Although only a few embodiments have been disclosed in detail above, other modifications are possible, and this disclosure is intended to cover all such modifications, and most particularly, any modification which might be predictable to a person having ordinary skill in the art.

Also, only those claims which use the words “means for” are intended to be interpreted under 35 USC 112, sixth paragraph. Moreover, no limitations from the specification are intended to be read into any claims, unless those limitations are expressly included in the claims.

1. A system comprising:
a first array of radiating antennas;
a second array of receiving antennas; and
a controller, which receives information from said second array, indicative of characteristics of an individual passing between said first array and said second array, and uses said characteristics to form a profile of characteristics of said individual.

2. A system as in claim 1, wherein said first array and said second array include a cover portion that hides said first array and said second array from view.

3. A system as in claim 1, wherein each of said first array and said second array is formed of an array antennas formed substantially with an edge of one antenna pressed against an edge of another antenna.

4. A system as in claim 1, wherein at least a plurality of said antennas of said first array are pointed at a plurality of said antenna of said second array.

5. A system as in claim 4, wherein the information received by said controller receives a plurality of points of information, each point of information forming a pixel of an image representing the individual.

6. A system as in claim 1, wherein said first array and said second array are located in a doorway.

7. A system as in claim 1, further comprising a database for said information maintaining information about locations of profiles of similar information at different times.

8. A system as in claim 1, wherein said antennas transmit microwave energy.

9. A system as in claim 8, wherein said microwave energy has a signal of substantially 150 GHz.

10. A system as in claim 8, wherein said microwave energy is transmitted at a level of 10 mW per centimeter squared, or less.

11. A system as in claim 8, wherein said microwave energy is used to illuminate a subject's body parts, to determine individual sizing information of said body parts.

12. A system as in claim 11, wherein said body parts include at least one of head size and shape, torso size and shape, and/or bone structure.

13. A method, comprising:
determining individual characteristics of an individual at a first monitoring location; and
using said individual characteristics for a security-related application without determining a specific identity of said individual.

14. A method as in claim 13, wherein said determining comprises using microwave energy to determine sizes of an individual's body parts.

15. A method as in claim 14, wherein said sizes of said individual's body parts include at least sizes of at least one of the head, neck, torso, and/or waist and hips.

16. A method as in claim 14, wherein said security related application comprises monitoring a location of said individual.

17. A method as in claim 14, wherein said individual characteristics are used for identifying the person.

18. A method as in claim 14, wherein said microwave energy is transmitted that a less than 10 milliwatts per centimeter squared.

19. A method as in claim 13, wherein said using comprises using said individual characteristics to determine if said individual is authorized for access to an area encompassing said first monitoring location.

20. A method as in claim 13, wherein said using comprises using said individual characteristics to monitor movements of the individual.

21. An apparatus comprising:
a first array of focused microwave transmitting antennas;
a microwave transmitting electronics, producing microwave signals for the first array;
a second array of focused microwave receiving antennas, each antenna of said second array being focused and pointed to receive a microwave transmission from a specific antenna of the first array; and
a control part, determining which elements of the second array have received transmissions, and determining parameters of human body shape based on which specific antennas of the array have been blocked, and forming a data file indicative of said parameters of human body shape.

22. An apparatus as in claim 21, further comprising a profile maintaining part, which maintains a profile based on one of said data files and different locations where said one of said data files has been seen, without recognizing an individual corresponding to said one of said data files.
